(19) United States
(12) Patent Application Publication
(10) Pub. No.: US 2010/0328864 A1
(43) Pub. Date: Dec. 30, 2010

(54) DISPLAY ELEMENT, ELECTRONIC DEVICE, AND MOBILE ELECTRONIC DEVICE

(75) Inventors: Toshiaki Yoshihara, Kawasaki (JP); Junji Tomita, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/878,152

(22) Filed: Sep. 9, 2010

Related U.S. Application Data
(63) Continuation of application No. PCT/JP2008/055308, filed on Mar. 21, 2008.

(51) Int. Cl. H05K 7/00; G02F 1/1347; G09G 5/00

(52) U.S. Cl. 361/679.01; 349/77; 345/204

(57) ABSTRACT

A display element includes a plurality of laminated display panels, each display panel having a material to control light sealed between two substrates, wherein at least in part of the display element, there is a portion where the number of the laminated display panels is different, a bent section is formed at the portion where the number of the laminated display panels is different, and electrodes may be provided or may not provided at the bent section.

### CROSS-REFERENCE TO RELATED APPLICATIONS

This application is a continuation application and is based upon PCT/JP2008/055308, filed on Mar. 21, 2008, the entire contents of which are incorporated herein by reference.

### FIELD

The embodiments discussed herein are related to a reflective display element, an electronic device and a mobile electronic device.

### BACKGROUND

In recent years, the development of electronic paper has been promoted in companies, universities, etc. As an applied market where electronic paper is expected, a variety of applied mobile devices have been proposed, including electronic books as its main application, a sub-display of mobile terminal equipment, and a display section of an IC card. One promising type of electronic paper is a display element that uses a liquid crystal composition in which a cholesteric phase is formed. The liquid crystal composition is cholesteric liquid crystal or chiral nematic liquid crystal. The term cholesteric liquid crystal is used. The cholesteric liquid crystal has excellent characteristics, such as semipermanently holding a display (memory properties), vivid color display, high contrast, and high resolution.

FIG. 1 schematically illustrates a cross-sectional configuration of a display element 10 capable of producing a full-color display using cholesteric liquid crystal. The display element 10 has a structure in which a blue (B) display panel section 10B, a green (G) display panel section, and a red (R) display panel section 10R are laminated in this order from the display surface. In the figure, the side of the upper substrate is the display surface and external light (solid line arrow) is incident toward the display surface from above the substrate. Above the substrate, the eye of a viewer and the direction of viewing (broken line arrow) are illustrated schematically.

The B display panel section 10B has a pair of upper and lower substrates 11B and 13B, a blue (B) liquid crystal layer 12B sealed between the substrates, and a blue drive circuit 18B that applies a predetermined pulse signal to an electrode on the substrate to apply a predetermined pulse voltage to the B liquid crystal layer 12B. Similarly, the G display panel section 10G has a pair of upper and lower substrates 11G and 13G, a green (G) liquid crystal layer 12G sealed between the substrates, and a green drive circuit 18G that applies a predetermined pulse voltage to the G liquid crystal layer 12G. The R display panel section 10R has a pair of upper and lower substrates 11R and 13R, a red (R) liquid crystal layer 12R sealed between the substrates, and a red drive circuit 18R that applies a predetermined pulse voltage to the R liquid crystal layer 12R. On the backside of the lower substrate 13R of the R display panel section, a light absorbing layer 17 is arranged.

The cholesteric liquid crystal used in each of the B, G, and R liquid crystal layers is a liquid crystal mixture, in which a comparatively large amount of additive having chiral properties (referred to also as chiral material) is added to the nematic liquid crystal so that the content will be a few tens of wt %. When a comparatively large amount of chiral material is contained in the nematic liquid crystal, it is possible to form a cholesteric phase in which the nematic liquid crystal molecules are strongly twisted into a helical form. Because of this, the cholesteric liquid crystal is referred to also as chiral nematic liquid crystal.

The cholesteric liquid crystal has bi-stability (memory properties) and may assume a planar state, a focal conic state, or an intermediate state where both states are mixed by adjusting the intensity of an electric field to be applied to the liquid crystal. Once the planar state, the focal conic state, or the intermediate state thereof is entered, the state is maintained stably without the presence of an electric field after that. For example, the planar state is obtained by applying a predetermined high voltage between the upper and lower electrodes to apply a strong electric field to the liquid crystal layer and after bringing the liquid crystal into a homeotropic state, rapidly reducing the electric filed to zero.

The focal conic state is obtained by, for example, applying a predetermined voltage lower than the above-mentioned high voltage between the upper and lower substrates to apply an electric field to the liquid crystal layer and then by rapidly reducing the electric field to zero. Alternatively, the focal conic state is obtained from the planar state by gradually applying a voltage.

The intermediate state of the planar state and the focal conic state is obtained, for example, by applying a voltage lower than the voltage by which the focal conic state is obtained between the upper and lower substrates to apply an electric field to the liquid crystal layer and then by rapidly reducing the electric field to zero.

FIG. 2A and FIG. 2B are diagrams for explaining the display principles of a liquid crystal display element that uses the cholesteric liquid crystal with the B display panel section 10B as an example. FIG. 2A illustrates a state of orientation of the liquid crystal molecules of the cholesteric liquid crystal when the B liquid crystal layer 12B of the B display panel section 10B is in the planar state. As illustrated in FIG. 2A, the liquid crystal molecules in the planar state sequentially rotate in the direction of thickness of substrate and form a helical structure and the helical axis of the helical structure becomes substantially perpendicular to the substrate surface.

In the planar state, light with a predetermined wavelength in accordance with the helical pitch of the liquid crystal molecules is reflected selectively from the liquid crystal layer. When an average refractive index is n and a helical pitch is p, then the wavelength λ with which reflection is maximum is expressed by λ=n·p.

Because of this, in order to cause the B liquid crystal layer 12B of the B display panel section 10B to reflect blue light selectively in the planar state, the average refractive index n and the helical pitch p are determined so that, for example, λ=480 nm. The average refractive index n may be adjusted by selecting a liquid crystal material and chiral material and the helical pitch p may be adjusted by adjusting the content of chiral material.

FIG. 2B illustrates the orientation state of the liquid crystal molecules of the cholesteric liquid crystal when the B liquid crystal layer 12B of the B display panel section 10B is in the focal conic state. As illustrated in FIG. 2B, the liquid crystal molecules in the focal conic state rotate sequentially in the direction of the substrate surface and form a helical structure and the helical axis of the helical structure becomes substantially parallel with the substrate surface. In the focal conic state, the selectivity of a wavelength to be reflected of the B liquid crystal layer 12B is lost and almost all incident light passes through. The light having passed through is absorbed by the light absorbing layer 17 arranged on the backside of the lower substrate 13B of the R display panel section 10B, and therefore, a dark (black) display may be realized.

In the intermediate state of the planar state and the focal conic state, the ratio between reflected light and transmitted light may be adjusted in accordance with the state, and therefore, the intensity of reflected light may be varied.

As described above, with the cholesteric liquid crystal, it is possible to control the amount of reflected light with the orientation state of the liquid crystal molecules twisted into the form of a helix.

In the same manner as that of the above-mentioned B liquid crystal layer 12B, a display element for full-color display is manufactured by sealing cholesteric liquid crystal that selectively reflects green or red light in the planar state into the G liquid crystal layer 12G and the R liquid crystal layer 12R, respectively.

As described above, by using cholesteric liquid crystal and laminating the display panels that selectively reflect red, green, and blue light, the display element having memory properties and capable of producing a full-color display may be obtained, and therefore, it is possible to produce a color display with zero power consumption except when the screen is rewritten.

The color liquid crystal display element using cholesteric liquid crystal is described in WO2006/103738A1, etc., and therefore, no further explanation is given.

As described above, electronic paper of various display schemes has been developed and Japanese Laid-open Patent Publication No. 2004-258477 describes electronic paper that may be bent like normal paper by making use of the characteristic of electronic paper that it is thin. The electronic paper that may be bent described in Japanese Laid-open Patent Publication No. 2004-258477 is one-layer electronic paper for a monochrome display and the configuration that enables the electronic paper to be folded completely like normal paper is described.

### RELATED DOCUMENTS

WO2006/103738A1

Japanese Laid-open Patent Publication No. 2004-258477

### SUMMARY

According to a first aspect of the embodiment, a display element includes a plurality of laminated display panels, each display panel having a material to control light sealed between two substrates, wherein at least in part of the display element, there is a portion where the number of the laminated display panels is different.

According to a second aspect of the embodiment, an electronic device includes a display section having a display element including a plurality of laminated display panels, each display panel includes a material to control light sealed between two substrates, wherein at least in part of the display element, there is a portion where the number of the laminated display panels is different.

According to a third aspect of the embodiment, an electronic device includes a display section, wherein the display section covers at least one surface of a case of the electronic device, a case pattern of the electronic device is displayed on the display section in a first state, and an image representing a second state is displayed in a partial area of the display section in the second state.

According to a fourth aspect of the embodiment, a mobile electronic device includes electronic paper provided on at least one surface of a case, wherein a design of external appearance may be changed by changing a display pattern and display color of the electronic paper.

The object and advantages of the embodiments will be realized and attained by means of the elements and combination particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a section view of a full-color liquid crystal display panel using cholesteric liquid crystal;

FIG. 2A is a diagram for explaining the display principles of a liquid crystal display element using cholesteric liquid crystal;

FIG. 2B is a diagram for explaining the display principles of a liquid crystal display element using cholesteric liquid crystal;

FIG. 3 is a schematic configuration diagram of a cholesteric liquid crystal display device used in an embodiment;

FIG. 4 is a diagram illustrating a configuration of a liquid crystal display element used in a cholesteric liquid crystal display device used in an embodiment;

FIG. 5 is a diagram illustrating a reflectance spectrum of a liquid crystal display element used in an embodiment;

FIG. 6 is a diagram illustrating the voltage-reflectance characteristic of a liquid crystal display element used in an embodiment;

FIG. 7 is a graph illustrating brightness of a display screen when a voltage pulse is applied cumulatively to cholesteric liquid crystal in a liquid crystal display element used in an embodiment;

FIG. 8A to FIG. 8D are diagrams illustrating an outline of a mobile telephone in a first embodiment;

FIG. 9 is a diagram illustrating a configuration of a control circuit and a drive circuit of a display element of the mobile telephone in the first embodiment;

FIG. 10 is a flowchart illustrating processing to change a case pattern in the mobile telephone in the first embodiment;

FIGS. 11A and 11B are diagrams illustrating an outline of a mobile telephone in a second embodiment;

FIG. 12A is a diagram illustrating an example of a structure of a liquid crystal display element used in the mobile telephone in the second embodiment;

FIG. 12B is a diagram illustrating a section of a state where the liquid crystal display element in FIG. 12A is bent;

FIG. 13A is a diagram illustrating another example of a structure of a liquid crystal display element used in the mobile telephone in the second embodiment;

FIG. 13B is a diagram illustrating a section of a state where the liquid crystal display element in FIG. 13A is bent;

FIG. 14A is a diagram illustrating another example of a structure of a liquid crystal display element used in the mobile telephone in the second embodiment;

FIG. 14B is a diagram illustrating a section of a state where the liquid crystal display element in FIG. 14A is bent;

FIG. 15A is a diagram illustrating another example of a structure of a liquid crystal display element used in the mobile telephone in the second embodiment;

FIG. 15B is a diagram illustrating a section of a state where the liquid crystal display element in FIG. 15A is bent;

FIG. 16A is a diagram illustrating another example of a structure of a liquid crystal display element used in the mobile telephone in the second embodiment;

FIG. 16B is a diagram illustrating a section of a state where the liquid crystal display element in FIG. 16A is bent;

FIG. 17A is a diagram illustrating another example of a structure of a liquid crystal display element used in the mobile telephone in the second embodiment;

FIG. 17B is a diagram illustrating a section of a state where the liquid crystal display element in FIG. 17A is bent;

FIGS. 18A and 18B are diagrams illustrating an outline of a mobile telephone in the embodiments;

FIG. 19 is a diagram illustrating a section in a state where a liquid crystal display element in the embodiments is bent;

FIG. 20 is a diagram illustrating another example of a structure of a liquid crystal display element;

FIG. 21 is a diagram illustrating a section of a state where the liquid crystal display element in FIG. 20 is bent;

FIG. 22A is a diagram illustrating another example of a structure of a liquid crystal display element;

FIG. 22B is a diagram illustrating a section of a state where the liquid crystal display element in FIG. 22A is bent;

FIG. 23 is a diagram illustrating another example of a structure of a liquid crystal display element;

FIG. 24 is a diagram illustrating a section of a state where the liquid crystal display element in FIG. 23 is bent;

FIG. 25A is a diagram illustrating another example of a structure of a liquid crystal display element;

FIG. 25B is a diagram illustrating a section of a state where the liquid crystal display element in FIG. 25A is bent;

FIG. 26A is a diagram illustrating another example of a structure of a liquid crystal display element;

FIG. 26B is a diagram illustrating a section of a state where the liquid crystal display element in FIG. 26A is bent.

### DESCRIPTION OF EMBODIMENTS

Before describing embodiments, desirable an appearance of a mobile electronic device, such as a mobile telephone are described.

In an electronic device, in particular, a mobile electronic device, such as a mobile telephone and PDA, the surface of a case is arranged outside in general to prevent an operation button etc. from being operated in a state of being carried. Explanation is given below with a mobile telephone as an example.

Conventionally, a plurality of models of mobile telephones are provided, of which the designs of external appearance, such as the shape of the case and the surface color of the case, are different and a user selects and purchases a favorite model. The design of external appearance of a mobile electronic device, such as a mobile telephone, including the surface color of the case is an important factor in sales and the sales depend largely on the design of external appearance.

As a mobile telephone, such one is widely used, on the case's outer surface of which, a display element capable of producing a simple display, such as a time display and an indicator display to notice an incoming call, is provided. Because of this, it is demanded to make it possible to design an external appearance including such a display element that appeals more strongly to users.

Further, as described above, in the case of a conventional mobile telephone, a user selects his/her favorite design of external appearance from among a plurality of predetermined models. In other words, it is not possible to change the design of external appearance of a mobile telephone after the purchase thereof. For example, there are provided products to be attached to a mobile telephone to change its external appearance. However, such a product is attached externally, and therefore, there are such problems that the size is increased and that it is difficult to realize a favorite design of external appearance because of its structure.

Embodiments to be explained below realize a new electronic device capable of further improving the design of external appearance and at the same time, realize a display element that enables the realization of such a new electronic device.

Preferred embodiments of the present invention will be explained with reference to accompanying drawings.

### First Embodiment

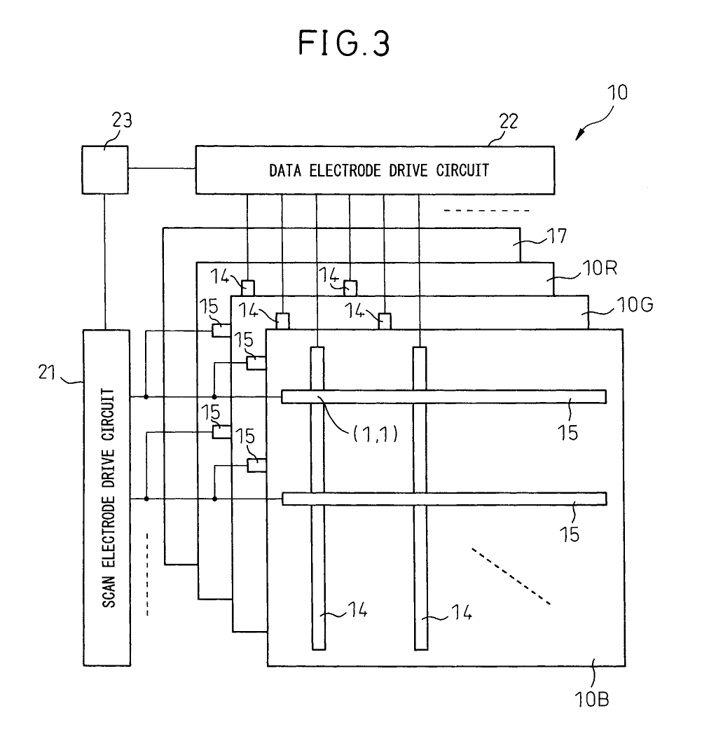

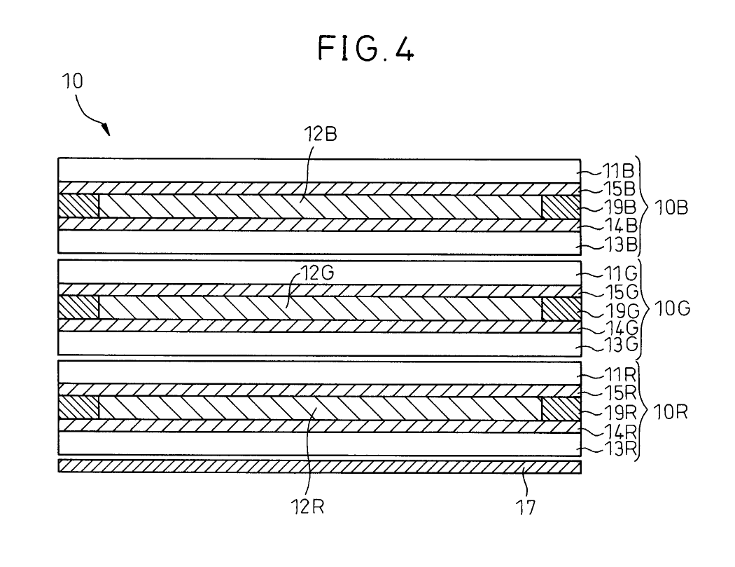

First, a liquid crystal display device that uses cholesteric liquid crystal for blue (B), green (G), and red (R), which is used in embodiments, to be described later, and a method of driving the same are explained using FIG. 3 to FIG. 7. FIG. 3 illustrates a schematic configuration of a display element 10 of a liquid crystal display device. FIG. 4 schematically illustrates a sectional configuration of a liquid crystal display element.

As illustrated in FIG. 3 and FIG. 4, the liquid crystal display element 10 has a B display section 10B comprising a blue (B) liquid crystal layer 12B that reflects blue light in a planar state, a G display section 10G comprising a green (G) liquid crystal layer 12G that reflects green light in the planar state, and an R display section 10R comprising a red (R) liquid crystal layer that reflects red light in the planar state. Each of the B, G, and R display sections is laminated in this order from the side of light incidence surface (display surface).

The B display section 10R has a pair of upper and lower substrates 11B and 13B arranged in opposition to each other and the B liquid crystal layer 12B sealed between both the substrates. The B liquid crystal layer 12B has B cholesteric liquid crystal adjusted to selectively reflect blue light.

The G display section 10G has a pair of upper and lower substrates 11G and 13G arranged in opposition to each other and the G liquid crystal layer 12G sealed between both the substrates. The G liquid crystal layer 12G has G cholesteric liquid crystal adjusted to selectively reflect green light.

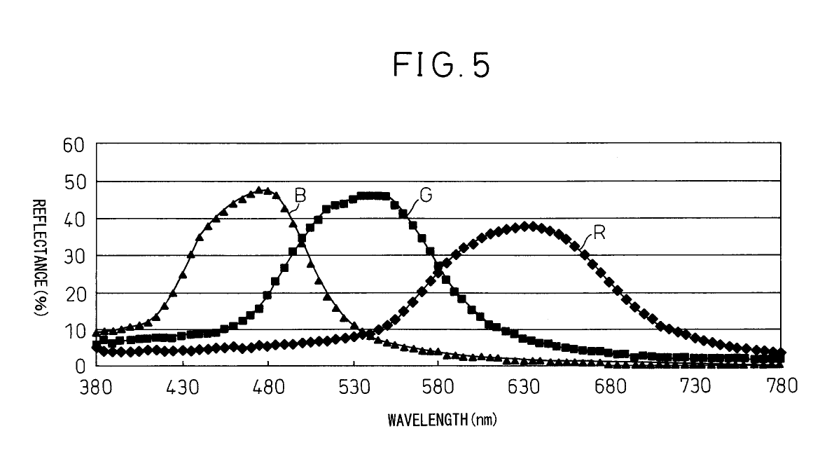

Similarly, the R display section 10R has a pair of upper and lower substrates 11R and 13R arranged in opposition to each other and the R liquid crystal layer 12R sealed between both the substrates. The R liquid crystal layer 12R has R cholesteric liquid crystal adjusted to selectively reflect red light. FIG. 5 illustrates reflectance spectra of the B display section 10B, the G display section 10G, and the R display section 10R in the planar state.

The liquid crystal composition is described in detail. The liquid crystal composition constituting a liquid crystal layer is cholesteric liquid crystal, which is a nematic liquid crystal mixture to which a chiral material of 10 to 40 wt % is added. The amount of added chiral material is the value when the total amount of the nematic liquid crystal component and the chiral material is assumed to be 100 wt %. As nematic liquid crystal, various nematic liquid crystal materials publicly known conventionally may be used. The refractive index anisotropy (Δn) is preferably 0.18 to 0.24. When the refractive index anisotropy is smaller than this range, the reflectance in the planar state is reduced and when larger than the range, the scattering reflection in the focal conic state is increased and in addition to that, the viscosity is increased and the response speed is reduced. The thickness of the liquid crystal is preferably 3 to 6 μm and when the thickness is smaller than this range, the reflectance in the planar state is reduced and when larger, the drive voltage becomes too high.

Next, the optical activity of each display section is described. In the laminated structure of each of the B, G, and R display sections, the optical activity in the G liquid crystal layer 12G in the planar state is made different from the optical activity in the B liquid crystal layer 12B and the R liquid crystal layer 12R, and therefore, in the area where the reflectance spectra of blue and green and the reflectance spectra of green and red overlap, it is possible, for example, to cause the B liquid crystal layer 12B and the R liquid crystal layer 12R to reflect the right-handed circularly polarized light and the G liquid crystal layer 12G to reflect the left-handed circularly polarized light. Due to this, it is possible to increase the brightness of the display screen of the liquid crystal display device by reducing the loss of reflected light.

The upper substrates 11B, 11G, and 11R and the lower substrates 13B, 13G, and 13R need to have translucency and in this example, they are constituted by a polycarbonate (PC) film substrate. Instead of a PC substrate, a glass substrate or a film substrate, such as polyethylene terephthalate (PET), may be used. In this example, both the upper substrates and the lower substrates have translucency; however, the lower substrate 13R of the R display section 10R arranged in the lowermost layer may be opaque.

On the side of the B liquid crystal layer 12B of the lower substrate 13B of the B display section 10B, a plurality of band-shaped data electrodes 14 extending in the vertical direction in FIG. 3 are formed in parallel with one another. On the side of the B liquid crystal layer 12B of the upper substrate 11B, a plurality of band-shaped scan electrodes 15 extending in the horizontal direction in FIG. 3 are formed in parallel with one another. The data electrode 14 and the scan electrode 15 are formed at a desired pitch by patterning a transparent electrode.

As illustrated in FIG. 3, when the electrode formation surfaces of the upper and lower substrates are viewed in the normal direction, both the electrodes are arranged in opposition to each other so as to intersect each other. Each intersection area of both the electrodes forms each pixel. Pixels are arrayed in a matrix to form the display screen.

As a material for forming both electrodes, for example, indium tin oxide (ITO) commonly used, however, a transparent conductive film of indium zinc oxide (IZO), a metal electrode of aluminum or silicon, or photoconductive film of amorphous silicon or bismuth silicon oxide (BSO) may be used.

It is preferable for the top of both the electrodes to be coated with alignment layers (none of them are illustrated schematically) to respectively control the insulating film and the array of liquid crystal molecules as functional layers. The insulating film has a function to prevent a short circuit between electrodes and to improve the reliability of a liquid crystal display device as a gas barrier layer. As an alignment layer, an organic film of polyimide resin, polyamide imide resin, polyetherimide resin, polyvinyl butyral resin, acryl resin, etc., or an inorganic material of silicon oxide or aluminum oxide may be used. In this example, the entire surface of the substrate on the electrode is coated with an alignment layer. The alignment layer may be used as an insulating thin film at the same time.

By a sealing material 19B applied to the outer circumference of the upper and lower substrates, the B liquid crystal layer 12B is sealed between both the substrates 11B and 13B. Further, it is necessary to keep uniform the thickness (cell gap) of the B liquid crystal layer 12B. A predetermined cell gap is maintained by dispersing spherical spacers made of resin or inorganic oxide in the B liquid crystal layer 12B or forming a plurality of cylindrical spacers in the B liquid crystal layer 12B. In this liquid crystal display device also, spacers (not illustrated schematically) are inserted in the B liquid crystal layer 12B to keep the uniformity of the cell gap. It is preferable for the cell gap in the B liquid crystal layer 12B to be 3 μm≦d≦6 μm.

The G display section 10G and the R display section 10R have the same structure as that of the B display section 10B, and therefore, their explanation is omitted. On the outer surface (backside) of the lower substrate of the R display section 10R, a visible light absorbing layer 17 is provided. Because of this, when all of the B, G, and R liquid crystal layers are in the focal conic state, black is displayed on the display screen of the liquid crystal display device. It may also be possible to provide a visible light absorbing layer only when necessary.

To the upper substrate (11B, 11G, 11R), a scan electrode drive circuit 21 in which a scan electrode driver IC to drive a plurality of the scan electrodes 15 is mounted is connected. To the lower substrate 13 (13B, 13G, 13R), a data electrode drive circuit 22 in which a data electrode driver IC to drive a plurality of data electrodes is mounted is connected. These drive circuits are configured to output a scan signal or a data signal to the predetermined scan electrode 15 or the data electrode 14 based on a predetermined signal output from a control circuit 23.

In this example, it is also possible to make substantially the same the drive voltage of each of the B, G, and R liquid crystal layers, and therefore, a predetermined output terminal of the scan electrode drive circuit 21 is commonly connected to each predetermined input terminal of the scan electrode of each of the B, G, and R display sections. It is no longer necessary to provide the scan electrode drive circuit for each of the B, G, and R display sections, and therefore, it is possible to simplify the configuration of the drive circuit of the liquid crystal display device. Making common the output terminal of the scan electrode drive circuits for B, G, and R may be performed in accordance with necessity.

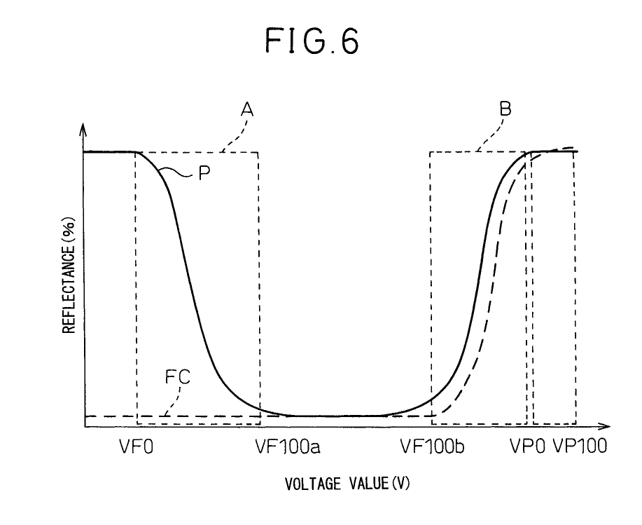

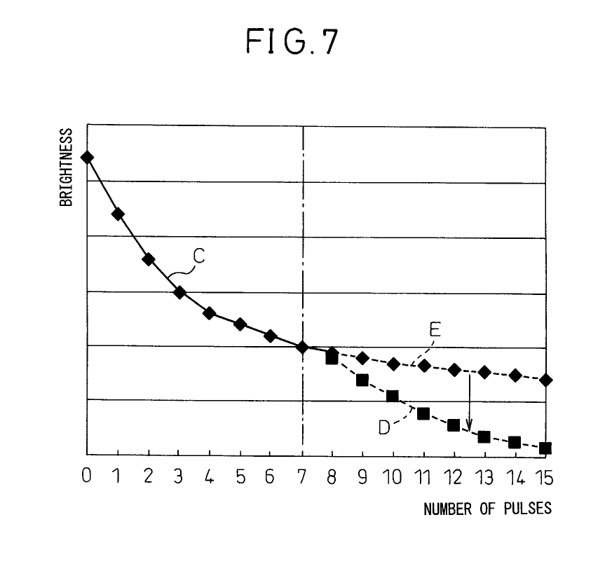

Next, an example of a method of driving a display device is explained using FIG. 6 and FIG. 7. In this example, a multi-gradation display is realized by cumulatively applying a voltage pulse to the liquid crystal in the pixel and reducing the gradation by making use of the cumulative response characteristic of the cholesteric liquid crystal. Each time a pulse voltage of a predetermined voltage value is applied to the cholesteric liquid crystal, the mixture ratio of the focal conic state is increased by the cumulative response characteristic, and thereby, it is possible to gradually transition from the planar state to the focal conic state. Alternatively, by making use of the cumulative response characteristic of the cholesteric liquid crystal, it is possible to gradually transition from the focal conic state to the planar state.

FIG. 6 illustrates an example of the voltage-reflectance characteristic of the general cholesteric liquid crystal. The horizontal axis represents the voltage value (V) of a pulse voltage to be applied with a predetermined width (for example, 4.0 ms (milliseconds)) between both electrodes that sandwich the cholesteric liquid crystal and the vertical axis represents the reflectance (%) of the cholesteric liquid crystal. A solid line curve P illustrated in FIG. 6 represents the voltage-reflectance characteristic of the cholesteric liquid crystal the initial state of which is the planar state and a broken line curve FC represents the voltage-reflectance characteristic of the cholesteric liquid crystal the initial state of which is the focal conic state.

In FIG. 6, if a predetermined high voltage VP100 (for example, ±36 V) is applied between both the electrodes to generate a relatively strong electric field in the cholesteric liquid crystal, the helical structure of the liquid crystal molecules is undone completely and a homeotropic state is brought about, where all of the liquid crystal molecules align in the direction of the electric field. When the liquid crystal molecules are in the homeotropic state, if the applied voltage is reduced rapidly from VP100 to 0 V or to a predetermined low voltage (for example, VF0=±4 V) to rapidly reduce the electric field in the liquid crystal almost to zero, the liquid crystal molecules are brought into the helical state, where the helical axis becomes substantially perpendicular to both the electrodes and the planar state is brought about, where light having a wavelength in accordance with the helical pitch is reflected selectively.

Further, according to the curve P illustrated in FIG. 6, in a frame A surrounded by broken lines, it is possible to reduce the reflectance of the cholesteric liquid crystal by increasing the voltage value (V) of the pulse voltage to be applied between both the electrodes. Furthermore, according to the curve P and the curve FC illustrated in FIG. 6, in a frame B surrounded by broken lines, it is possible to reduce the reflectance of the cholesteric liquid crystal by reducing the voltage value (V) of the pulse voltage to be applied between both the electrodes.

The basic principles of a multi-gradation display of the display device illustrated as an example are explained using FIG. 7. FIG. 7 is a graph illustrating the brightness of the display screen when a voltage pulse is applied cumulatively to the cholesteric liquid crystal. The horizontal axis represents the number of applied voltage pulses and the vertical axis represents brightness. The characteristic of the liquid crystal display element illustrated as an example is represented by a curve C in the figure when the number of pulses is 0 to 7 and represented by a curve D in the figure when the number of pulses is 8 to 15. On the side of low gradation (curve D), the response characteristic to pulse is low compared to that on the side of high gradation (curve C), and therefore, a pulse with a great width is used. As an example, when the pulse width when the number of voltage pulses is 0 to 7 is supposed to be 1, the pulse width when the number of pulses is 8 to 15 is set to 3. A curve E represents the characteristic when the pulse width is set to 1 also on the side of low gradation.

By making use of the characteristics of the above-described reset processing and write processing, it is possible to realize a color display by controlling the voltage to be applied to each of the B, G, and R display sections.

The configuration of the display device (electronic paper) using cholesteric liquid crystal is explained as above. In embodiments to be explained below, embodiments in which the cholesteric liquid crystal is used are explained; however, it is also possible to use electronic paper other than the electronic paper that uses cholesteric liquid crystal.

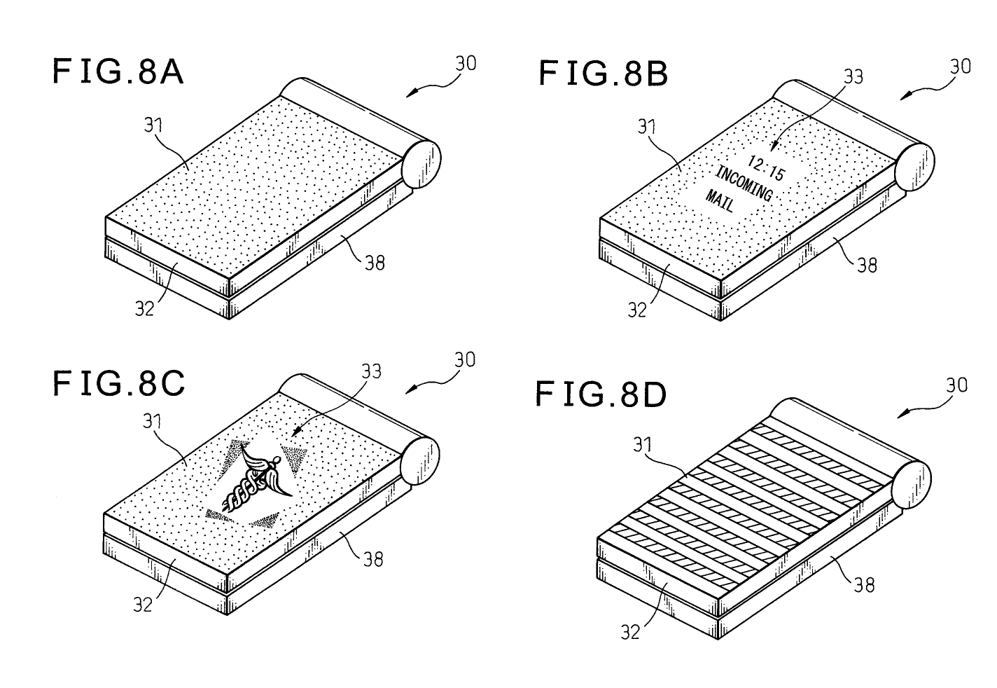

FIGS. 8A to 8D are diagrams illustrating an external appearance of a mobile telephone (mobile electronic device) 30 in the first embodiment. The mobile telephone 30 in the first embodiment is a folding type and FIGS. 8A to 8D illustrate a folded state. As illustrated in FIG. 8A, in the folded state, the case surface and the side surface of the mobile telephone 30 form its external appearance. In the following explanation, an upper case is taken as an example, however, the same configuration may be applied to a lower case 38. When the mobile telephone 30 is used as a telephone, the case is opened and a user operates the telephone while watching the display screen capable of producing a motion picture provided on the backside of the upper case. In a conventional mobile telephone, on the case surface in the folded state, generally, a simple display device, such as a segment display device that displays time and displays an incoming call or mail, is provided.

In the mobile telephone 30 in the first embodiment, the surface of the upper case that appears when the telephone is folded is configured by electronic paper 31 of cholesteric liquid crystal. The surface of the upper case is substantially flat, and therefore, conventional electronic paper of cholesteric liquid crystal may be used as it is.

As illustrated in FIG. 8A, in a non-display state where no patter display is produced, the entire surface of the electronic paper 31 is, for example, blue and the case looks like a blue case. When the electronic paper 31 produces a monochrome display, it is possible to change brightness. Consequently, it is possible to turn the case color into black. When the electronic paper 31 produces a full-color display, it is possible to change color and brightness. As described above, in the non-display state, the whole of the display section is the same color, and therefore, the uniformity of the display section may be maintained. Further, the external appearance of the case does not change so frequently, and therefore, if electronic paper that uses cholesteric liquid crystal having memory properties is used, power is consumed at the time of change; however, after the change, the changed display may be maintained with zero power consumption.

Because the electronic paper 31 on the case surface is capable of producing a pattern display, a display is produced in an area that requires a display in accordance with necessity. FIG. 8B illustrates a case where time is displayed and a display 33 indicative of an incoming call and mail are produced in the folded state, i.e., a case where the electronic paper 31 produces a time display and the incoming display 33. The display may be produced so that display data comes up from the uniform background and the boundary between the display section and the case, which used to be seen in a conventional electronic device, may be eliminated. Power is consumed when an incoming display is produced; however, an incoming display is produced only when there is an incoming call or mail, and therefore, the actual power consumption is very small. Further, for the time display in units of minutes illustrated in FIG. 8B, the display needs to be rewritten once a minute, and therefore, power consumption is small. Furthermore, if only the part to be changed is rewritten, the power consumption may be further reduced.

Because the electronic paper 31 of the case surface is capable of producing a pattern display, it is also possible to display a pattern as illustrated in FIGS. 8C and 8D when not in use. FIG. 8C illustrates a case where a picture pattern is displayed and FIG. 8D displays a stripe. In other words, as part of the design of external appearance of the case, a picture pattern or stripe is displayed. This image is a gray-scale image in the case of monochrome electronic paper, or a color image in the case of color electronic paper. It is of course possible to produce the display 33 as illustrated in FIG. 8B together as part of an image.

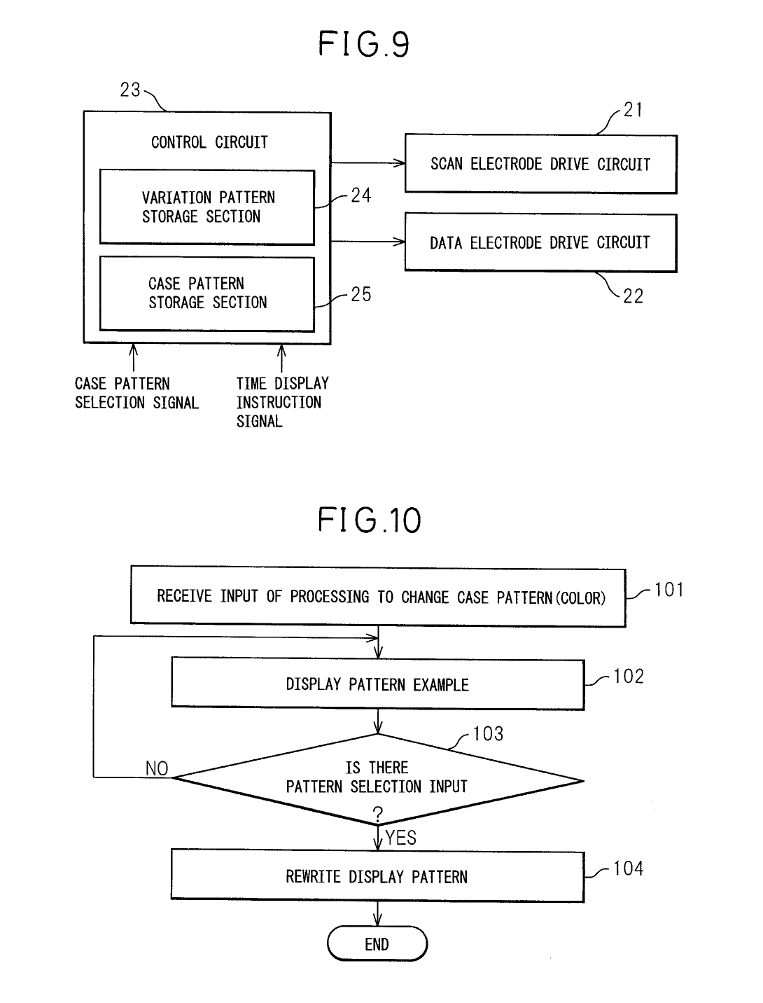

The mobile telephone 30 in the first embodiment has a drive circuit of electronic paper as illustrated in FIG. 3. FIG. 9 is a diagram illustrating a configuration of a drive circuit in the first embodiment. As illustrated schematically, the control circuit 23 has a variation pattern storage section 24 that stores pattern data for a time display and incoming display and a case pattern storage section 25 that stores case patterns as illustrated in FIGS. 8(A), (C), and (D). When instructed to produce a time display, the control circuit 23 reads the time display data in accordance with the time from the variation pattern storage section 24 and outputs the data to the scan electrode drive circuit 21 and the data electrode drive circuit 22 to rewrite the display of the electronic paper 31 so as to display the time. For the time display in units of minutes, each time the value of a time counter advances one minute, the time to be displayed is updated by performing the same operation. When there is an incoming call or mail, a corresponding incoming display pattern is read from the variation pattern storage section 24 and a display is produced. When displaying a blinking incoming display pattern, the control section 23 repeatedly reads an incoming display pattern corresponding to blinking from the variation pattern storage section 24 and produces a display. This display is maintained for a predetermined time to suppress power consumption.

When a case pattern selection signal is input, the control circuit 23 reads a specified case pattern from the case pattern storage section 25 and rewrites the display of the electronic paper 31. When no time display nor incoming display is produced, the case pattern is displayed all over the surface; however, when a time display or incoming display is produced, the time display or the incoming display is produced preferentially to the case pattern in an area where a time display or incoming display is to be produced.

FIG. 10 is a flowchart illustrating processing to change a case pattern. This processing is performed in the normal use state where the mobile telephone is open.

In step 101, a user inputs with a key an instruction to perform processing to change the case pattern (color) and the instruction is received.

In step 102, examples of the case patterns stored in the case pattern storage section 25 are displayed on the operation screen. A user performs processing to select a desired case pattern while watching the case patterns displayed.

In step 103, whether a patter selection is input is determined and when no pattern selection is input, the flowchart returns to step 102 and this operation is repeated until a pattern selection is input. When a pattern selection is input, the flowchart advances to step 104.

In step 104, the selected case patter is read from the case pattern storage section 25 and the case pattern is changed by rewriting the display of the electronic paper.

In the mobile telephone in the first embodiment, the electronic paper 31 is provided on the surface of the upper case of the mobile telephone; however, from the viewpoint of the design of external appearance, there is a case where it is desirable that the upper case surface continue up to the side surface. Further, it is possible to improve the usability of a user by making it possible to produce a simple display on the side surface of the case.

### Second Embodiment

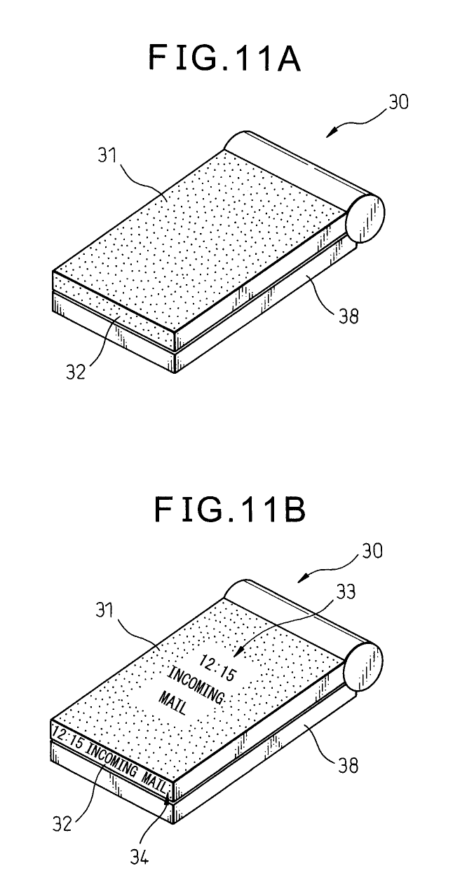

FIGS. 11A and 11B are diagrams illustrating the external appearance of the mobile telephone (mobile electronic device) 30 in a second embodiment. The mobile telephone 30 in the second embodiment has a configuration similar to that of the mobile telephone in the first embodiment; however, different in that the electronic paper 31 provided on the upper case surface extends up to the side surface at the front so that a side surface part 32 located on the side surface is provided. The electronic paper 31 may be monochrome or full-color one.

FIG. 11A illustrates a non-display state where no pattern display is produced, wherein the part of the top surface of the case and the side surface at the front are covered with the continuous electronic paper 31 and they look like a case of the same color.

FIG. 11B illustrates a case where the display 33 and a display 34, i.e., a time display and an incoming call or mail display, are produced on the case surface and the side surface at the front. As described above, it is possible to produce a display also on the side surface of the case of the mobile telephone, and a new display system may be realized, and therefore, it is possible to improve usability. In FIG. 11B, the content of the display 33 on the top surface of the case is the same as the content of the display 34 on the side surface; however, different contents may also be displayed.

The mobile telephone in the second embodiment is the same as the mobile telephone in the first embodiment except for those explained above. The case pattern may be the same color all over the surface of the electronic paper 31 including the side surface; however, it is also possible to change the color partially. The rewrite of the case pattern, etc., is performed in the same manner as that in the first embodiment.

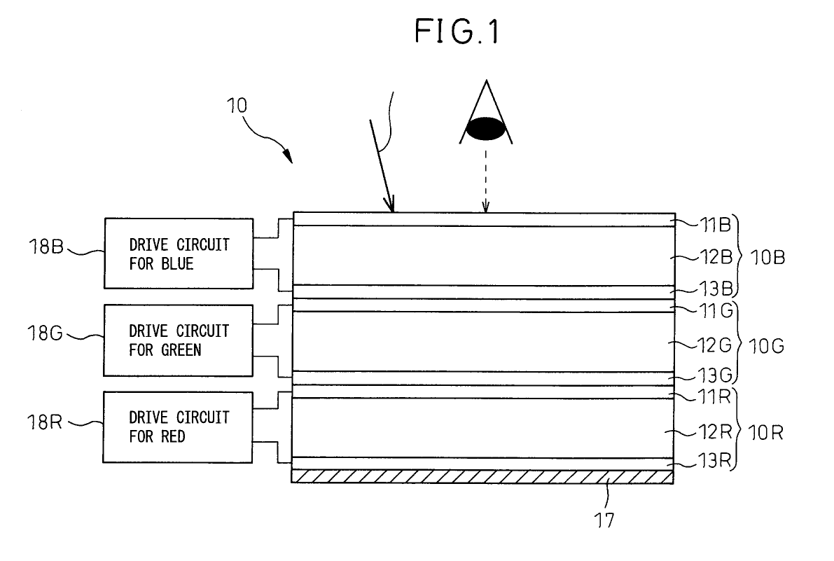

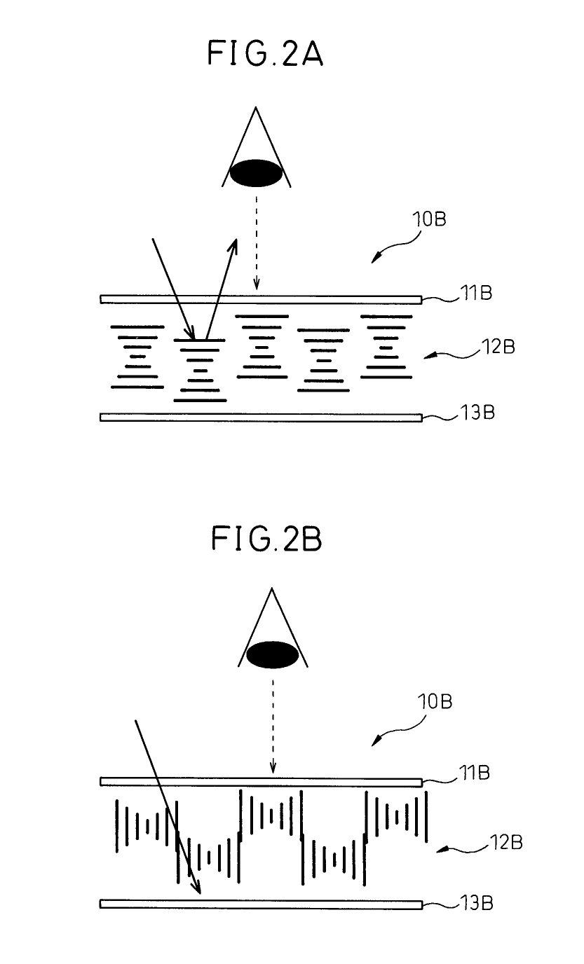

As described above, in the mobile telephone in the second embodiment, the electronic paper on the top surface of the case extends up to the side surface and there is a bent section. As illustrated in FIG. 1, the color electronic paper that uses cholesteric liquid crystal has a structure in which the B display panel section 10B, the G display panel section 10G, and the R display panel section 10R are laminated. Each display panel section is thin, however, when three display panel sections are laminated, it becomes thick and difficult to bend. Next, an example of a structure of color electronic paper that uses cholesteric liquid crystal, suitable for the use in the mobile telephone in the second embodiment, is explained.

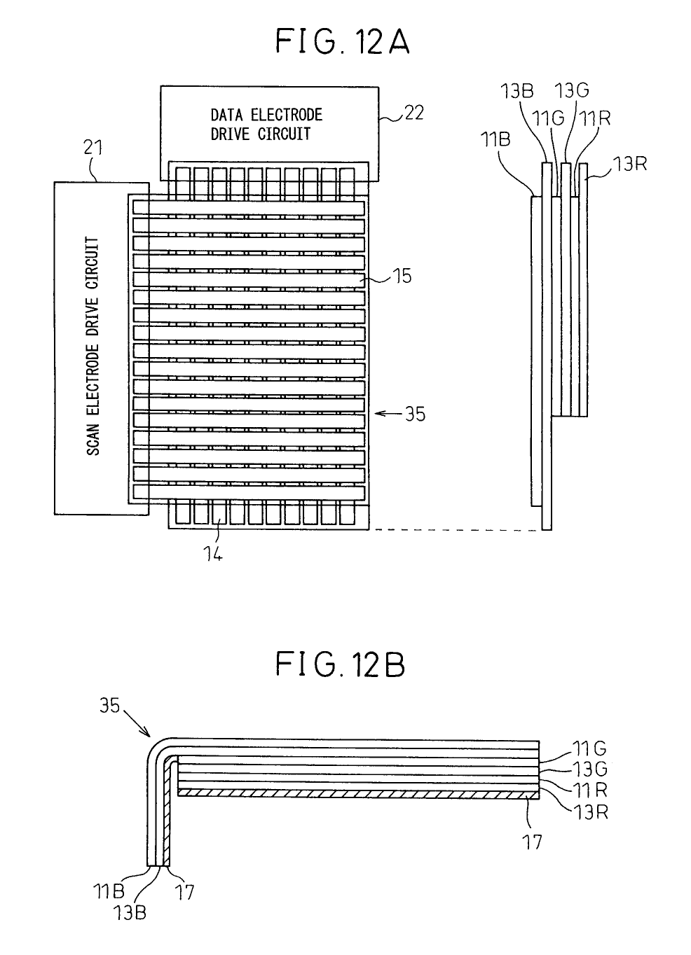

FIG. 12A and FIG. 12B are diagrams illustrating a first structure example of color electronic paper. The figure is illustrated with modified dimensions for easier understanding. First, a method of manufacturing the B display panel section 10B of the electronic paper in the first structure example is explained.

As illustrated in FIG. 12A, on the two polycarbonate (PC) film substrates 11B and 13B corresponding to the upper and lower substrates, an IZO transparent electrode is formed and patterned by etching, and thus stripe-shaped electrodes (the scan electrodes 15 or the data electrodes 14) are formed.

Next, a polyamide-based alignment layer material is applied with a thickness of about 700 Å by spin coat on the respective stripe-shaped transparent electrodes on the two PC film substrates. Next, the two PC film substrates to which the alignment layer material is applied is subjected to baking processing for an hour in a oven at 120° C. and thus an alignment layer is formed.

Next, an epoxy-based sealing compound is applied to the peripheral part on the one of the PC film substrates using a dispenser. Next, spacers the size of the particle diameter are dispersed on the other PC film substrate and an adjustment is made so that the panel gap (liquid crystal layer thickness) becomes about 4 μm. Next, the two PC film substrates are bonded to each other and heated for one hour at 160° C., and thus, the sealing compound is hardened. Due to this, the sealing material 19B is formed. Next, after injecting the B cholesteric liquid crystal by the vacuum injection method, the injection inlet is sealed with the epoxy-based sealing material and thus the B display section 10B is manufactured.

By the same method, the G display panel section 10G and the R display panel section 10R are manufactured, however, the size of the G display panel section 10G and the R display panel section 10R is reduced by an amount corresponding to the size beyond a bent section 35 as illustrated in FIG. 12A.

Next, a driver (segment driver) IC to drive liquid crystal is crimped to the terminal part of the respective data electrodes 14 of the B, G, and R display panel sections. (not illustrated schematically). Because of this, it is possible to drive the respective data electrodes 14 of the B, G, and R display panel sections independently of one another. This driver IC forms the data electrode drive circuit 22 in FIG. 12A. On the other hand, the scan electrodes of the B, G, and R display panel sections are connected to the common terminal part and a driver (common driver) IC to drive liquid crystal is crimped to the terminal part (not illustrated schematically). Because of this, the scan electrodes of the B, G, and R display panel sections are driven commonly. This driver IC forms the scan electrode drive circuit 21 in FIG. 12A. In other words, the data electrode drive circuit 22 and the scan electrode drive circuit 21 illustrated in FIG. 12A include the driver IC.

Subsequently, as illustrated in FIG. 12A and FIG. 12B, the B, G, and R display panel sections are laminated in this order from the display surface side. Next, the visible light absorbing layer 17 is arranged on the backside of the lower substrate 13R of the R display panel section 10R and the backside of the lower substrate 13B of the B display panel section 10B beyond the bent section 35. Finally, a power source circuit and a control circuit are connected. In this manner the display device is completed.

In the above-mentioned configuration, the display element has one layer of the B display panel section at the bent section 35, and therefore, the display element becomes easy to bend. Further, the display panel section having the bent section 35 is located at the outermost part (the uppermost surface) side, and therefore, a continuous, uniform display may be maintained with the display color of the display panel section at the outermost part (the B display panel section 10B in the present embodiment).

In this example of structure, on one of the sides demarcated by the bent section 35, it is possible to produce a full-color matrix display and on the other side, it is possible to produce a monochrome matrix display, and therefore, a display including a large amount of information may be produced.

Although not illustrated schematically, by providing an input/output device (not illustrated schematically) and a controller (also not illustrated schematically) that totally controls the whole of the device to the completed display device, the electronic paper is completed.

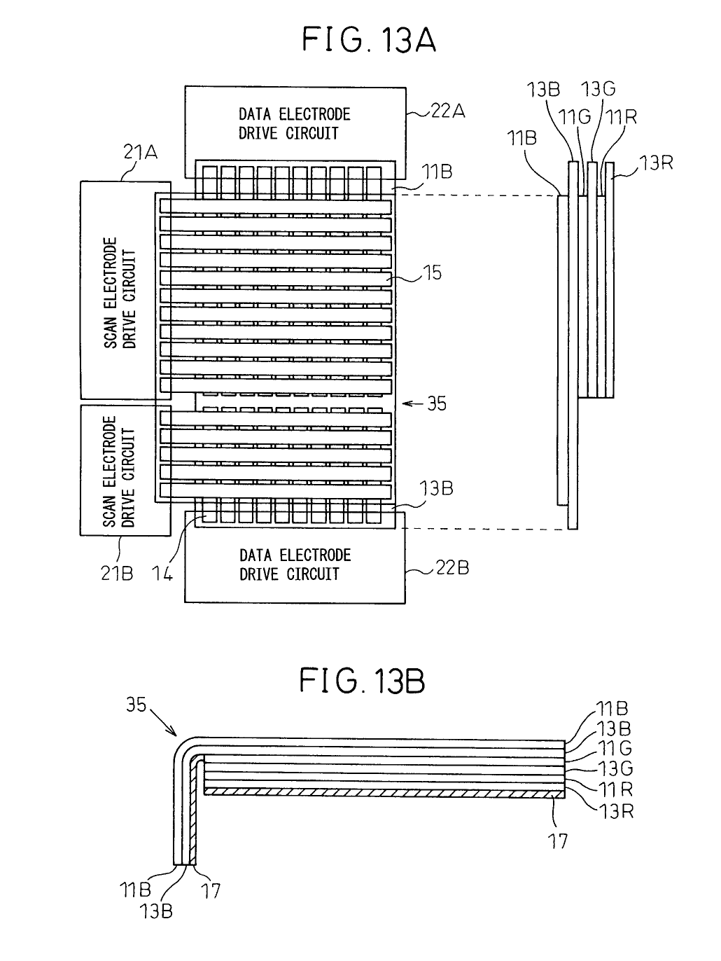

FIG. 13A and FIG. 13B are diagrams illustrating a second structure example of color electronic paper. In the case of the second structure example, the B display panel section 10B, the G display panel section 10G, and the R display panel section 10R are manufactured as in the first structure example, however, no electrode is provided at the bent section 35 in the B display panel section 10B as illustrated in FIG. 13A. Due to this, the breakage at the bent section 35 may be suppressed and a bending with a larger curvature may be realized.

As illustrated in FIG. 13A, a data electrode drive circuit 22A and a scan electrode drive circuit 21A that drive the data electrode 14 and the scan electrode 15 of the B, G, and R display panel sections on one of the sides of the bent section 35 are provided. Further, a data electrode drive circuit 22B and a scan electrode drive circuit 21B that drive the data electrode 14 and the scan electrode 15 of the B display panel section 10B beyond the bent section 35 are provided. The scan electrode drive circuits 21A and 21B may be integrated into one unit. The data electrode drive circuit 22A drives the data electrodes of the B, G, and R display panel sections independently. The scan electrode drive circuit 21A drives the scan electrodes of the B, G, and R display panel sections commonly. The data electrode drive circuit 22B drives the data electrode of the B display panel section 10B. The scan electrode drive circuit 21B drives the scan electrode of the B display panel section 10B.

Other parts in the second structure example are the same as those in the first structure example, and their explanation is omitted.

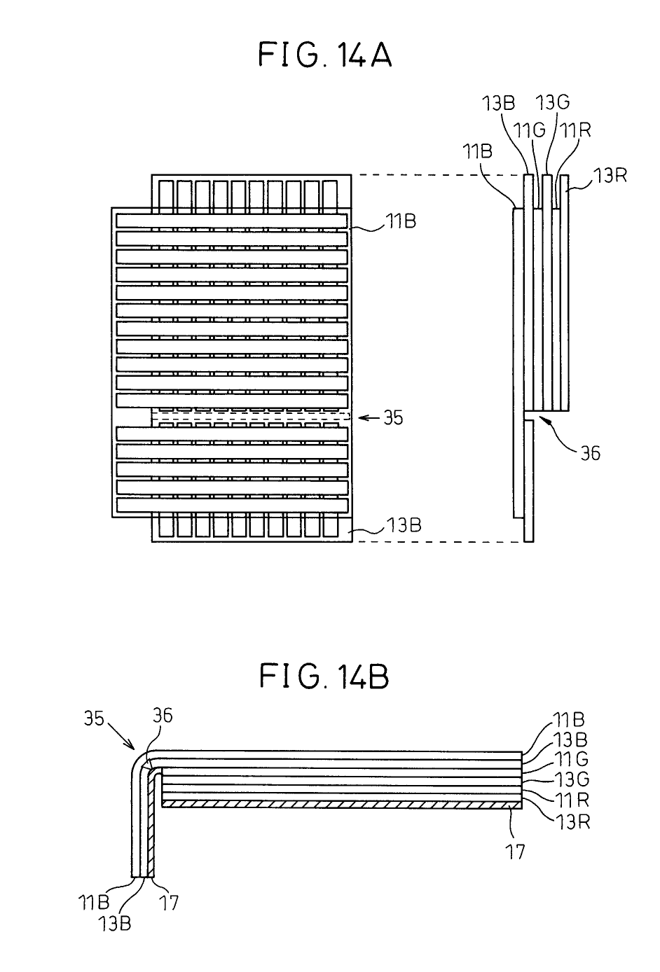

FIG. 14A and FIG. 14B are diagrams illustrating a third structure example of color electronic paper. In the third structure example, as illustrated in FIG. 14A and FIG. 14B, no electrode is provided at the bent section 35 but a notch 36 is provided on the film substrate 13B inside the bent section 35. Due to this, the breakage at the bent section may be suppressed and a bending with a larger curvature may be realized. Even when the notch 36 is provided, if the film substrate 13B remains as it is, no problem will arise in particular, however, if part of the film substrate 13B is removed completely, it is preferable to provide a sealing material to that part.

Other parts in the third structure example are the same as those in the second structure example, and therefore, their explanation is omitted. The data electrode drive circuit 22A, the scan electrode drive circuit 21A, the data electrode drive circuit 22B, and the scan electrode drive circuit 21B are also provided, however, they are not illustrated schematically. This also applies to the subsequent figures.

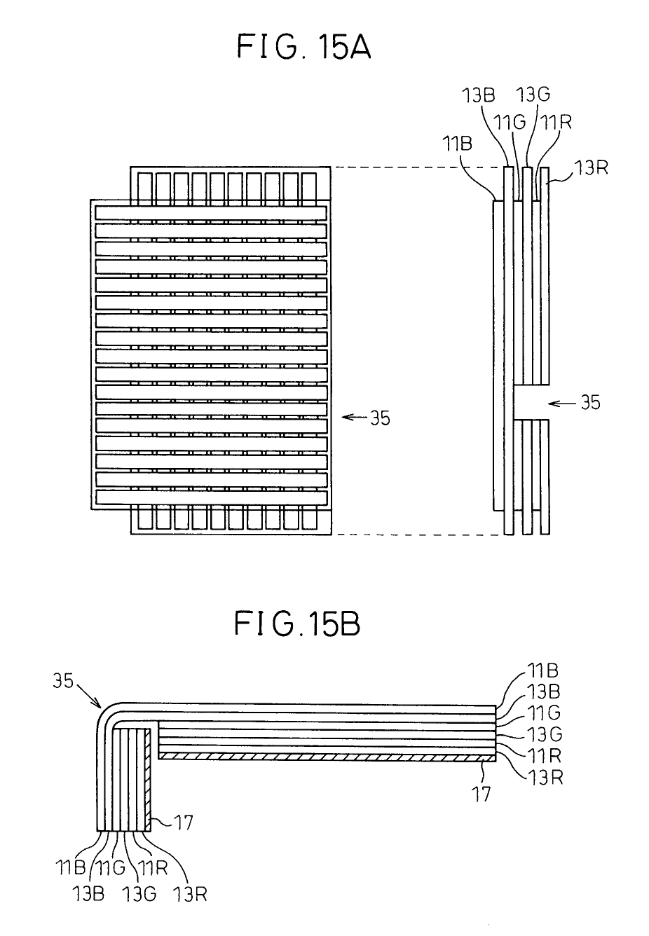

FIG. 15A and FIG. 15B are diagrams illustrating a fourth structure example of color electronic paper. The fourth structure example differs from the first structure example in that the G display panel section 10G and the R display panel section 10R are laminated on the part of the B display panel section 10B beyond the bent section 35 in the first structure example and thus it is made possible to produce a full-color matrix display, as illustrated in FIG. 15A and FIG. 15B.

In order to manufacture the electronic paper in the fourth structure example, only the B display panel section 10B is manufactured as a single unit and the G display panel section 10G and the R display panel section 10R are manufactured and laminated, individually, while being adjusted to the size of the display section demarcated by the bent section 35. It is necessary to provide a data electrode drive circuit to drive the data electrodes 14 of the B, G, and R display panel sections on one of the sides of the bent section 35 and a data electrode drive circuit to drive the data electrodes 14 of the G and R display panel sections beyond the bent section 35. At the part of the bent section 35, there are no scan electrodes of the G and R display panel sections to be driven by the scan electrode drive circuit 21.

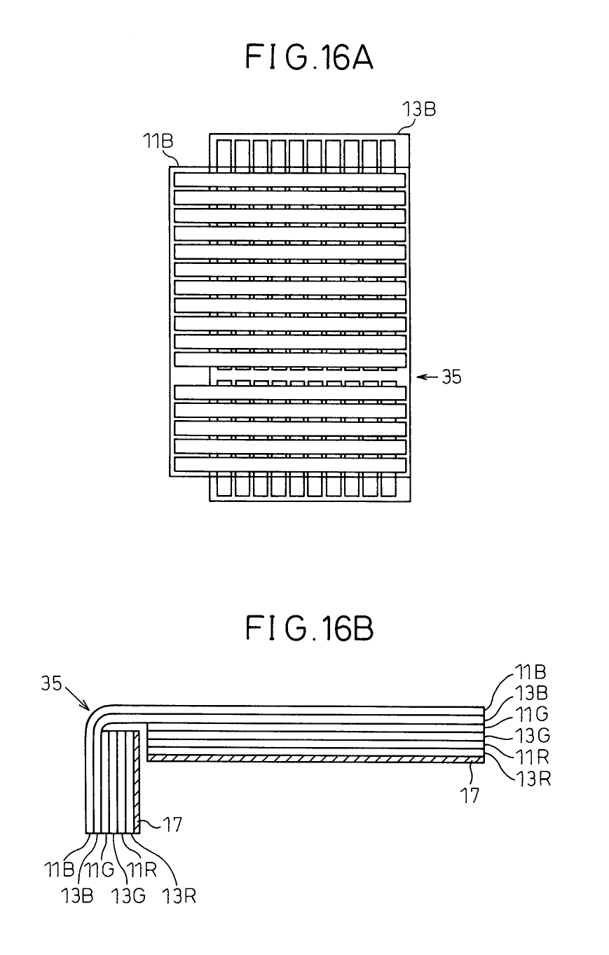

FIG. 16A and FIG. 16B are diagrams illustrating a fifth structure example of color electronic paper. As illustrated in FIG. 16A and FIG. 16B, the fifth structure example differs from the second structure example in that the G display panel section 10G and the R display panel section 10R are laminated on the part of the B display panel section 10B beyond the bent section 35 in the second structure example and thus it is made possible to produce a full-color matrix display. In other words, in the fifth structure example, no electrode is provided at the part of the bent section 35 in the fourth structure example. Other parts are the same as those in the second structure example and the fourth structure example, and therefore, their explanation is omitted.

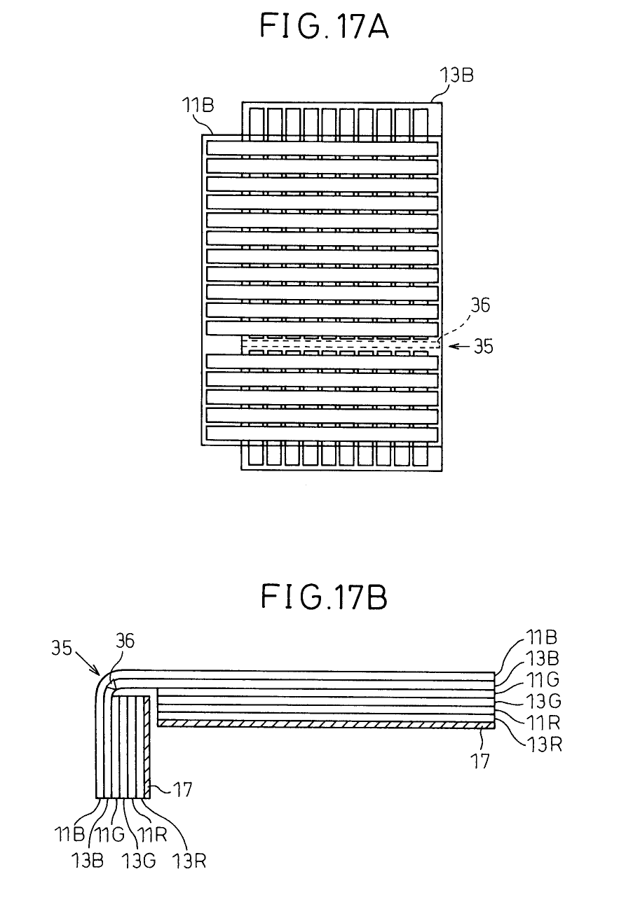

FIG. 17A and FIG. 17B are diagrams illustrating a sixth structure example of color electronic paper. The sixth structure example differs from the third structure example in that the G display panel section 10G and the R display panel section 10R are laminated on the part of the B display panel section 10B beyond the bent section 35 in the third structure example and thus it is made possible to produce a full-color matrix display. In other words, in the sixth structure example, the notch 36 is provided at the part of the bent section 35 in the fifth structure example. Other parts are the same as those in the third structure example and the fifth structure example, and therefore, their explanation is omitted.

By the use of the electronic paper in the first to sixth structure examples as explained above in the mobile telephone (mobile electronic device) in the second embodiment, it is possible to produce a full-color display on the surface of the case and at least a monochrome display at the bent section and on the side surface.

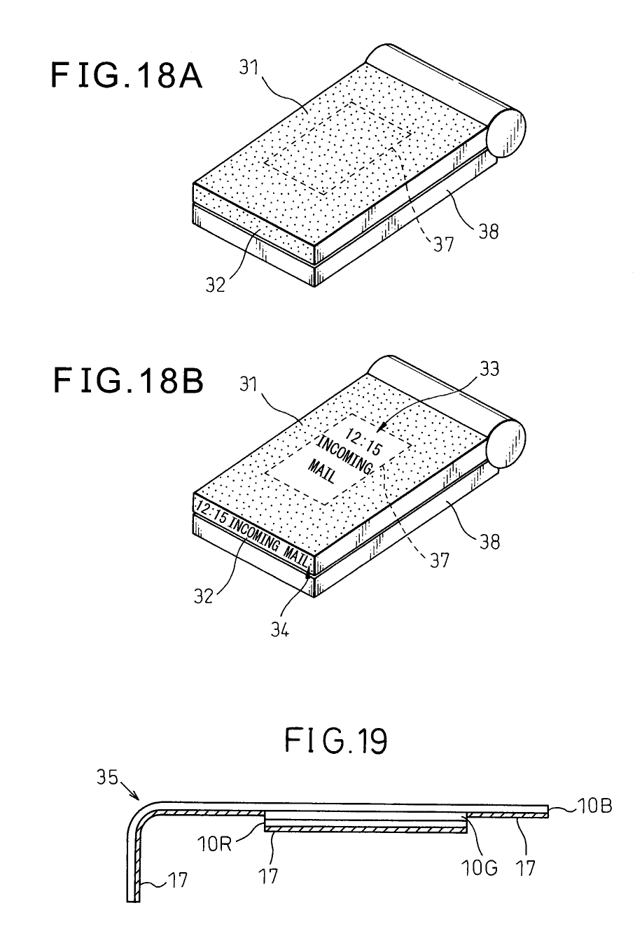

The design may be modified so that a full-color display may be produced on all over the surface of the case in the folded state as described above, however, it is also possible to limit an area 37 in which a full-color display is produced to part of the case surface as illustrated in FIGS. 18A and 18B. This is effective both in the first embodiment and in the second embodiment.

In an example in FIG. 18B, the electronic paper 31 produces a full-color display in the area 37 on the case surface, a monochrome display that displays the case color in the other area on the case surface, and a monochrome data display on the side surface.

FIG. 19 is a section view of a configuration of electronic paper that realizes such a display as illustrated in FIG. 18B. As illustrated schematically, the display panel sections 10G and 10G are laminated only on the part corresponding to the area 37 on the single display panel section 10B. On the entire backside, the light absorbing layer 17 is provided.

It is obvious that there may be various modified examples of the embodiments explained as above. Other structure examples that enable various modified examples are explained below.

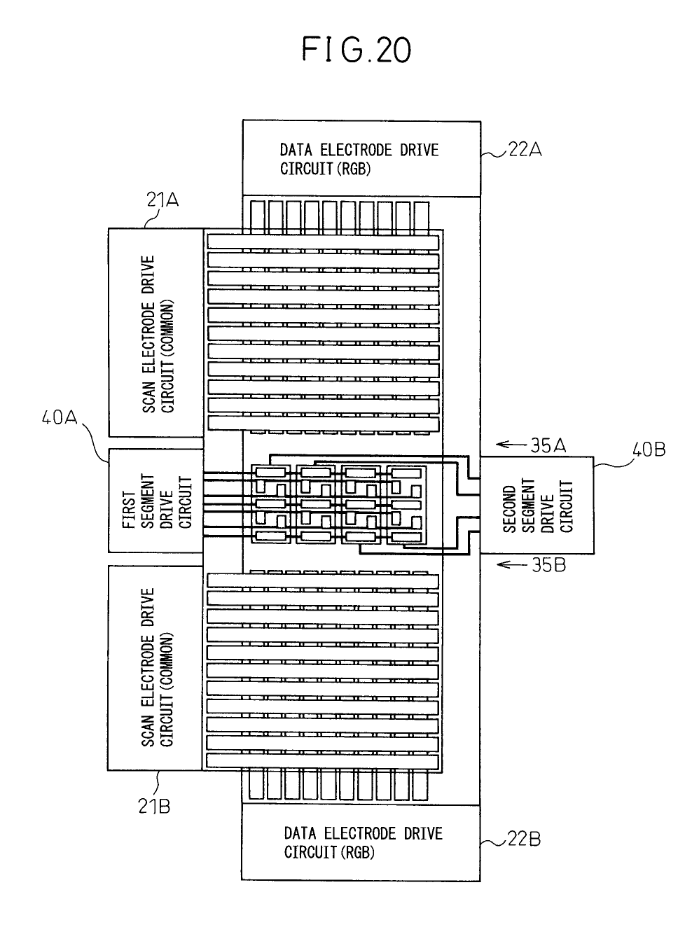

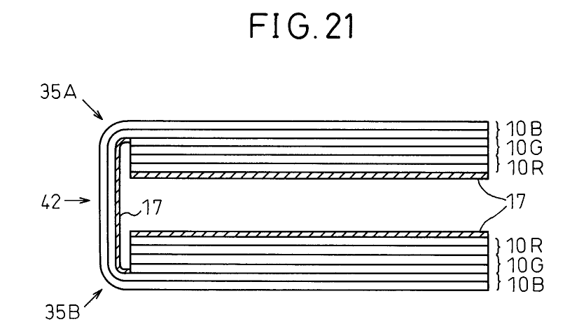

FIG. 20 and FIG. 21 are diagrams illustrating a seventh structure example of color electronic paper. As illustrated in FIG. 20 and FIG. 21, the seventh structure example is electronic paper that may be arranged on both sides of the case and which may produce a full-color matrix display on both sides of the case and a monochrome segment display on a side surface 42.

As illustrated in FIG. 20 and FIG. 21, in the B display panel section 10B, electrodes are formed and demarcated by two bent sections 35A and 35B so that a matrix display, a segment display, and a matrix display may be produced in this order and a display panel section having these electrodes are manufactured as a single unit. The G display panel section 10G and the R display panel section 10R are manufactured individually and laminated with their sizes being adjusted to the sizes of the display sections demarcated by the bent sections. The data electrode drive circuit 22A drives the respective data electrodes of the B, G, and R display panel sections on the upper side of the bent section 35A independently, the data electrode drive circuit 22B drives the respective data electrodes of the B, G, and R display panel sections on the lower side of the bent section 35A independently, the scan electrode drive circuit 21A drives the scan electrodes of the B, G, and R display panel sections on the upper side of the bent section 35A commonly, the scan electrode drive circuit 21B drives the scan electrodes of the B, G, and R display panel sections on the lower side of the bent section 35A commonly, and a first segment drive circuit 40A and a second segment drive circuit 40B drive the segment electrodes between the bent sections 35A and 35B.

In the seventh structure example also, the bent section is located at the outermost part (uppermost surface), and therefore, it is possible to display a continuous, uniform case color with the display color of the display panel section at the outermost part (the B display panel section in the present embodiment).

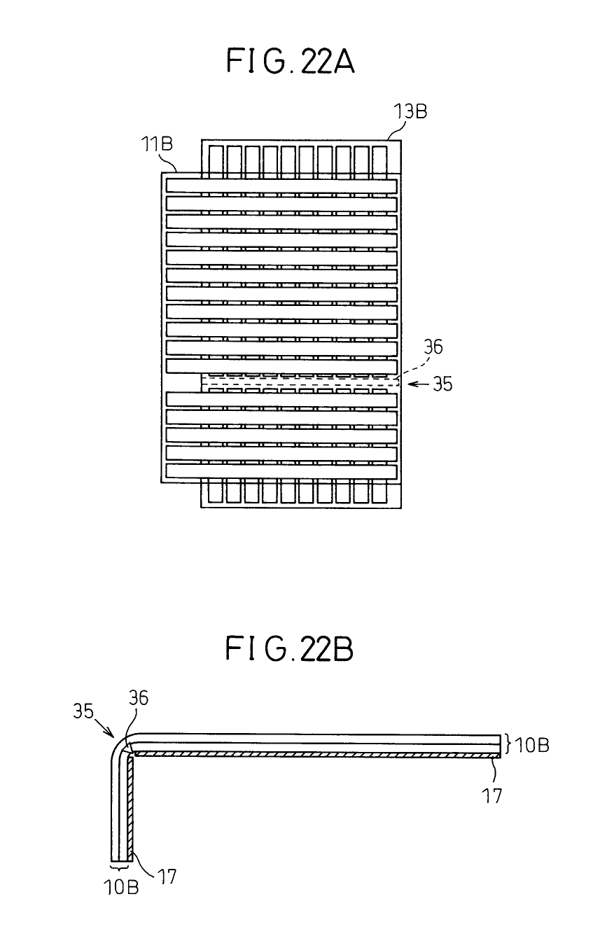

FIG. 22A and FIG. 22B are diagrams illustrating an eighth structure example of color electronic paper. As illustrated in FIG. 22A and FIG. 22B, with the electronic paper in the eighth structure example, it is possible to produce a monochrome (blue) matrix display on the single display panel section (the blue display panel section 10B) forming the entire surface. On the backside of the blue display panel section 10B, the light absorbing layer 17 is provided. In order to make it easier to bend the bent section 35, the notch 36 is provided.

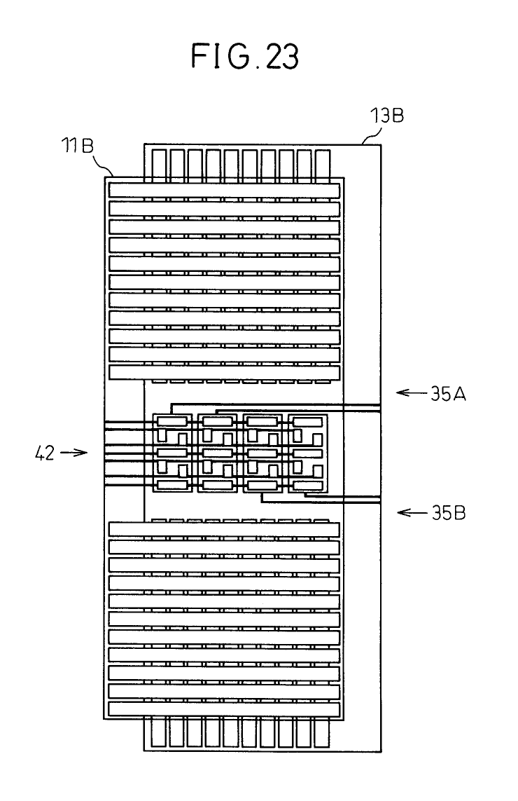

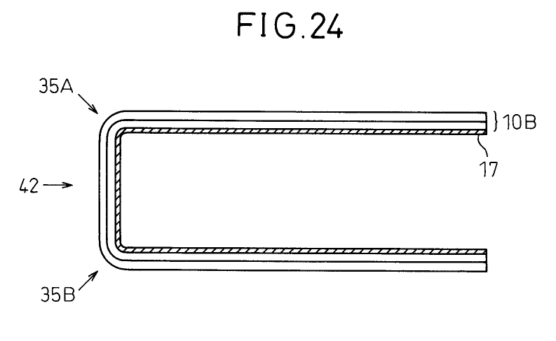

FIG. 23 and FIG. 24 are diagrams illustrating a ninth structure example of color electronic paper. As illustrated in FIG. 23 and FIG. 24, with the electronic paper in the ninth structure example, it is possible to produce a monochrome (blue) matrix display on the single display panel section (the blue display panel section 10B) forming the entire surface. On the backside of the blue display panel section 10B, the light absorbing layer 17 is provided. In the area 42 between the two bent sections 35A and 35A, a monochrome segment display is produced and at the part on both sides of the two bent sections 35A and 35A, a monochrome matrix display is produced.

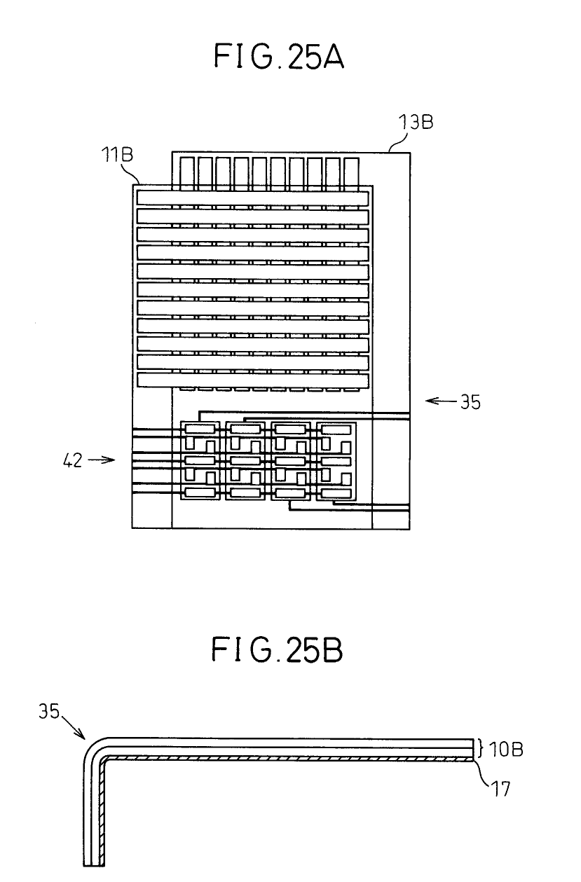

FIG. 25A and FIG. 25B are diagrams illustrating a tenth structure example of color electronic paper. As illustrated in FIG. 25A and FIG. 25B, with the electronic paper in the tenth structure example, it is possible to produce a monochrome (blue) matrix display on the single display panel section (the blue display panel section 10B) forming the entire surface. On the backside of the blue display panel section 10B, the light absorbing layer 17 is provided. In one of the areas of the bent section 35, a monochrome matrix display is produced and in the other area of the bent section 35, a monochrome segment display is produced.

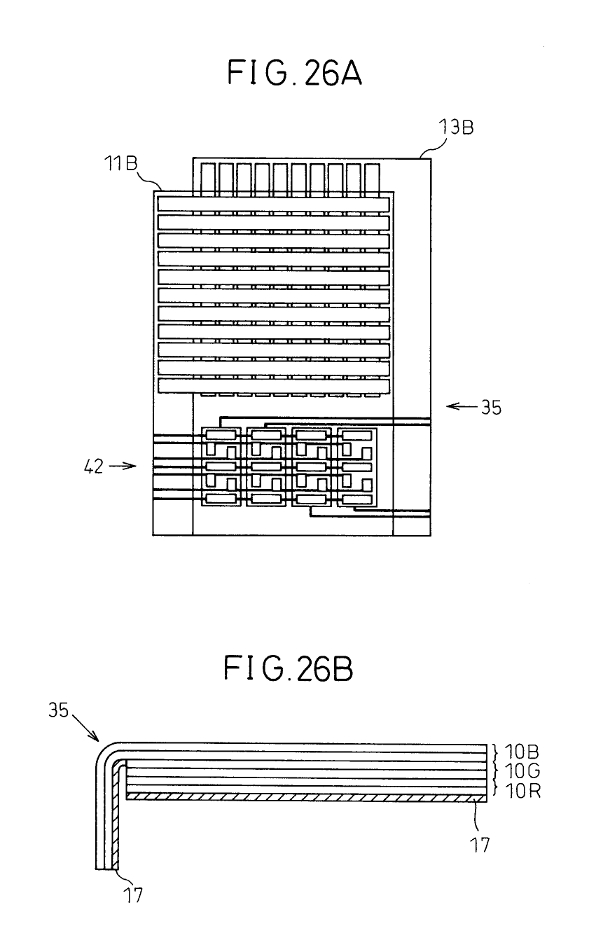

FIG. 26A and FIG. 26B are diagrams illustrating an eleventh structure example of color electronic paper. As illustrated in FIG. 26A and FIG. 26B, with the electronic paper in the eleventh structure example, a full-color matrix display is produced in one of the areas of the bent section 35 and a monochrome segment display is produced in the other area of the bent section 35. In the area in which a full-color matrix display is produced, the G and R display panel sections 10G and 10R are laminated on the B display panel section 10B. On the backside, the light absorbing layer 17 is provided.

In the embodiments explained above, the outermost display panel section is assumed to be the B display panel section, however, it is obvious that the same effect may be obtained even if the outermost display panel section is assumed to be a display panel section other than the B display panel section. Further, it is desirable to arrange the display panel section with the case color as the outermost display panel section, however, another display panel section may be arranged as the outermost display panel section.

The examples with one or two bent sections are given as above, however, there may be two or more bent sections. Further, as the laminated structure, the example of the three-layer (RGB) structure is given; however, it is obvious that the same effect may be obtained with a structure having layers the number of which is not three.

As explained above, according to the embodiments explained above, it is possible to obtain a uniform display section. In particular, it is possible to bend the display device comprising a plurality of display panel sections in which a material to control light is sealed inside the sandwich-shaped substrate and further, to secure the continuity and uniformity at the display section.

Further, according to the embodiments explained above, the electronic devices are desirable to provide the following matters.

It is desirable that the electronic device is provided with a display section that covers at least one surface of a case of the electronic device and the whole of the display section has the same color in the non-display state. It is desirable for the display section to be a display element having memory properties, such as electronic paper.

With such an electronic device, it is possible to produce a time display and an indicator display to notice an incoming call on a part that looks like a surface of the case, not a display section in the non-display state. Due to this, in the display state, it is possible to produce a display of data that seems to come up from a uniform background, and therefore, it is made possible to design an external appearance that attracts users because there is not a boundary between the display section and the case, which used to be present in the conventional example. It is not necessary to produce an indicator display to notice an incoming call at all times and for a time display in units of minutes, the display needs to be rewritten about once a minute, and therefore, for a display element having memory properties, the power consumption may be reduced. It may also be possible to design the electronic device so that only the part of the display section on which a display of data is produced has a multilayer structure capable of producing a color display and the other part has a single-layer structure for producing a monochrome display of the case color.

Further, in order to realize the above-mentioned object, an electronic device disclosed here is provided with electronic paper on at least one surface of a case and it is made possible to change the design of external appearance by changing the display pattern/display color of the electronic paper.

It is possible for a user only to select the design of external appearance at the time of purchase of an electronic device but not possible to change the design of external appearance of the electronic device. In contrast to this, with the above-mentioned electronic device, electronic paper forms the surface of the case, in other words, electronic paper forms the design of external appearance, and therefore, it is possible to change the design of external appearance by changing the display pattern/display color of the electronic paper. For example, with monochrome electronic paper having one layer, it is possible to change the surface color into various gradations between the color of the electronic paper and black or change the state of the part of the electronic paper between a state where the entire surface has the same color and a state where a pattern, such as stripe, is produced on the surface. It is of course possible to produce a time display and a display to notice an incoming call. If color electronic paper is used, it is possible to realize a further varied design of external appearance.

Because electronic paper has memory properties, it is possible to maintain the state after changed without consuming energy. It is not necessary to frequently change the design of external appearance, and therefore, with electronic paper having memory properties, there arise no problem of energy consumption.

When a display element, such as electronic paper, is provided on the surface of the case of an electronic device, if the display element is provided on the case surface, which is substantially flat, a conventional display element that uses cholesteric liquid crystal may be used as it is. In order to achieve a more flexible design of external appearance, however, it is desirable for the display element to be one that covers one surface of the case and extends up to the neighboring surface, that is, one having a bent section. In other words, it is desirable for a display element to be capable of securing the continuity of a display even if there is a bent section.

A color display element (electronic paper) that uses cholesteric liquid crystal has a configuration in which a plurality of display panels having different colors of reflected light and a light absorbing layer are laminated. However, the configuration may be such one in which two display panels and a light absorbing layer are laminated.

It is desirable that three layers of panel be present also at a bent section and a full-color display may be produced; however, if three layers of panel are laminated, the thickness is increased accordingly and the part becomes hard to bend. Because of this, the configuration is designed so that part of the display element is provided with a part with a different number of laminated layers, in particular, so that the number of layers of display panel at the bent section is small, for example, as it were a single layer. Due to this, it is possible to reduce the curvature of bending compared to the case where a plurality of display panels are bent, and therefore, the degree of freedom in the design of external appearance is improved. Further, it is not necessary to considerably change the respective display panels and to manufacture the respective display panels in the same process, and therefore, the configuration is more excellent in cost and productivity. In this case also, the display color of one layer of panel is continuous at the bent section and it is possible to realize the continuity and uniformity of the case color.

No electrode is provided on at least one of the substrates in the area corresponding to the bent section of the display panel. Due to this, is it possible to prevent breakage of the electrode due to bending and to reduce the curvature of bending by an amount corresponding to the absence of the electrode.

It is desirable to arrange the display panel having a bent section so as to be located nearest to the viewing side of the plurality of laminated display panels. Due to this, the continuity (uniformity) of the display may be maintained. If the display panel having a bent section is located in the middle or at the lowest, it is not possible to realize sufficient continuity because of the difference in level of the display panel at the bent section.

It may also be possible to provide a matrix display section on both sides of the bent section or to provide a matrix display section on one side of the bent section and a segment display section on the other side. When the matrix display section is provided on both sides of the bent section, it is possible to produce a display with a large area and a large amount of information. When the matrix display section is provided on one side of the bent section and the segment display section is provided on the other side, it is possible to simultaneously produce a matrix display with a large amount of information and a segment display that is simple and convenient and the reduction in size accompanying the reduction in size of the frame and the reduction in cost may be achieved compared to the case where the matrix display section is provide on both sides.

It may also be possible to provide a plurality of laminated display panels on one side of the bent section and a smaller number of layers of display panel on the other side, or to provide a plurality of laminated display panels on both sides of the bent section.

When a plurality of laminated display panels are provided on one side of the bent section and a smaller number of layers of display panel is provided on the other side, it is possible to realize a multi-color display and a monochrome color display in accordance with necessity, and a uniform display may be produced, which has the display color of the display panel having a bent section, a curvature, and continuity. When a plurality of laminated display panels are provided on both sides of the bent section, a multi-color display may be produced in a wide range and a uniform display of the case color may be produced, which has the display color of the display panel having a bent section, a curvature, and continuity.

It may also be possible to provide a notch in a bent section so that the curvature at the bent section may be reduced as small as possible.

It may also be possible to provide a plurality of bent sections, and thereby, a bent structure with a high degree of freedom may be realized.

It is desirable that a material to be sealed between two substrates of the display panels to control light be cholesteric liquid crystal or chiral nematic liquid crystal. In other words, it is desirable that a display element (electronic paper) be one that uses cholesteric liquid crystal or chiral nematic liquid crystal. By using such a material, it is possible to easily realize a color display and memory properties of a display.

It is possible to set a display panel that uses cholesteric liquid crystal or chiral nematic liquid crystal so that each pixel exhibits a state of reflecting light, a state of transmitting light, and an intermediate state between them, and thereby, blue light, green light, and red light are reflected respectively. By laminating such display panels, it is possible to realize a reflective color display element with multi-gradation and multi-color display. In the reflective color display element, a liquid crystal display panel that reflects blue light, a liquid crystal display panel that reflects green light, and a liquid crystal display panel that reflects red light are laminated in this order from the viewing side and it is desirable that the optical activity of at least one reflected light, for example, the optical activity of green light, be different from the optical activity of another reflected light. Due to this, it is made possible to efficiently reflect incident light and to achieve a bright, reflective color display element. In particular, a light absorbing layer to absorb light is arranged at the lowest part on the opposite side of the viewing side, and therefore, it is possible to efficiently absorb light not reflected and to realize a display with a high contrast ratio.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A display element comprising a plurality of laminated display panels, each display panel having a material to control light sealed between two substrates, wherein
at least in part of the display element, there is a portion where the number of the laminated display panels is different.

2. The display element according to claim 1, wherein
at the portion where the number of the laminated display panels is different, a bent section is formed.

3. The display element according to claim 2, wherein
the bent section is not provided with an electrode.

4. The display element according to claim 2, wherein
the display panel having the bent section is located on the side of the display panel nearest to the viewing side of the plurality of laminated display panels.

5. The display element according to claim 2, wherein
a matrix display is produced on both sides of the bent section.

6. The display element according to claim 2, wherein
a matrix display is produced on one of the sides of the bent section and a segment display is produced on the other side.

7. The display element according to claim 2, having a plurality of laminated display panels on one of the sides of the bent section and a single layer display panel on the other side.

8. The display element according to claim 2, having a plurality of laminated display panels on both sides of the bent section.

9. The display element according to claim 2, wherein
the display panel having the bent section has a notch in the bent section.

10. The display element according to claim 2, having a plurality of bent sections.

11. The display element according to claim 1, wherein
the material that controls light is cholesteric liquid crystal or chiral nematic liquid crystal.

12. The display element according to claim 1, comprising the three display panels, wherein
each pixel in each panel becomes a state of reflecting light, a state of transmitting light, and an intermediate state of reflecting part of light and transmitting the rest of light, and
the three panels reflect blue light, green light, and red light, respectively.

13. The display element according to claim 1, wherein
the three display panels are laminated in order of the display panel that reflects blue light, the display panel that reflects green light, and the display panel that reflects red light from the viewing side.

14. The display element according to claim 1, wherein
the optical activity of reflected light of at least one of the plurality of display panels is different from the optical activity of reflected light of the other display panels.

15. The display element according to claim 1, wherein electrodes are formed and demarcated by two bent sections so that a matrix display, a segment display, and a matrix display are produced in this order, the display element further comprises: a data electrode drive circuit and a scan electrode drive circuit which drive electrodes of the matrix display on the upper side of the bent section; a data electrode drive circuit and a scan electrode drive circuit which drive electrodes of the matrix display on the lower side of the bent section; and first and second segment drive circuits which drive electrodes of the segment display.

16. The display element according to claim 1, further comprising a light absorbing layer that absorbs light arranged on the opposite side of the viewing side of the plurality of the laminated display panels.

17. An electronic device having a display section comprising a display element including a plurality of laminated display panels, each display panel having a material to control light sealed between two substrates, wherein at least in part of the display element, there is a portion where the number of the laminated display panels is different.

18. An electronic device comprising a display section, wherein
the display section covers at least one surface of a case of the electronic device,
a case pattern of the electronic device is displayed on the display section in a first state, and
an image representing a second state is displayed in a partial area of the display section in the second state.

19. The electronic device according to claim 18, wherein
the display section has memory properties.

20. A mobile electronic device, having electronic paper provided on at least one surface of a case, wherein
the design of external appearance may be changed by changing a display pattern and display color of the electronic paper.
